(19) United States
(12) Patent Application Publication
(10) Pub. No.: US 2012/0162909 A1
(43) Pub. Date: Jun. 28, 2012

(54) CONTAINER DATA CENTER

(75) Inventors: WEN-TANG PENG, Tu-Cheng (TW); YI-LIANG HSIAO, Tu-Cheng (TW)

(73) Assignee: HON HAI PRECISION INDUSTRY CO., LTD., Tu-Cheng (TW)

(21) Appl. No.: 13/070,461

(22) Filed: Mar. 23, 2011

(30) Foreign Application Priority Data
Dec. 24, 2010 (TW) 99145669

(51) Int. Cl. G06F 1/16; H05K 5/02

(52) U.S. Cl. 361/679.58; 312/223.2

(57) ABSTRACT

An exemplary container data center includes a container and racks received in the container. The container includes a bottom wall. Each of the racks includes four elongated beams respectively positioned on four corners of the rack and a plurality of connecting pieces for connecting the beams together. The four beams cooperatively define an accommodating space therebetween for receiving servers therein. Two of the connecting pieces are adjacent to the bottom wall of the container and are fixed on the bottom wall by fasteners.

### BACKGROUND

1. Technical Field

The present disclosure relates to container data centers.

2. Description of Related Art

Container data centers are becoming more popular. Commonly, racks for holding computer equipment are welded in place. Therefore, if a different layout in the center is needed, the racks must be cut away and re-welded, which is expensive and inconvenient.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views, and all the views are schematic.

FIG. 1 is an isometric view of a container data center according to an embodiment of the present invention, the container data center including a plurality of racks holding a multiplicity of servers.

FIG. 2 is an enlarged, isometric view of one of the racks of FIG. 1, but showing only two servers held in the rack.

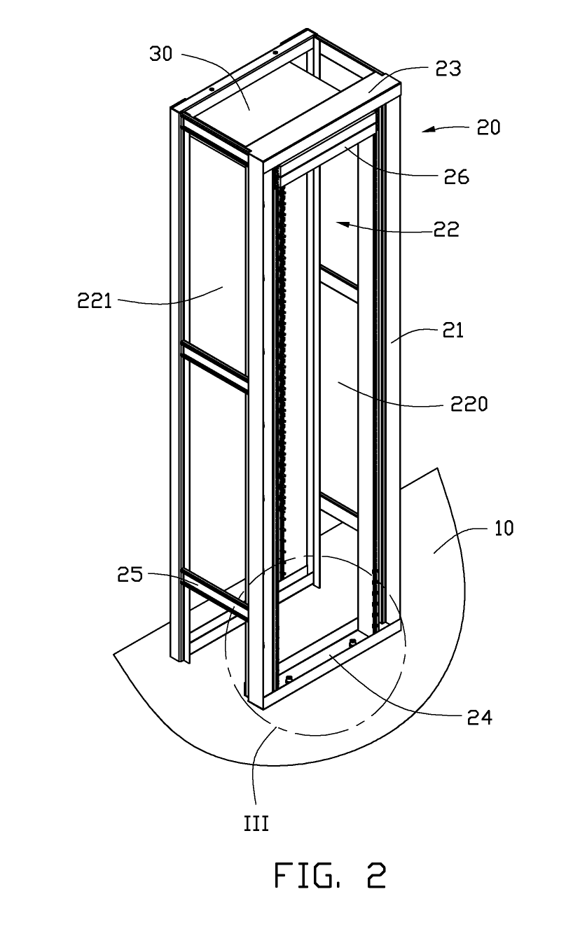

FIG. 3 is an enlarged view of a circled portion III of FIG. 2.

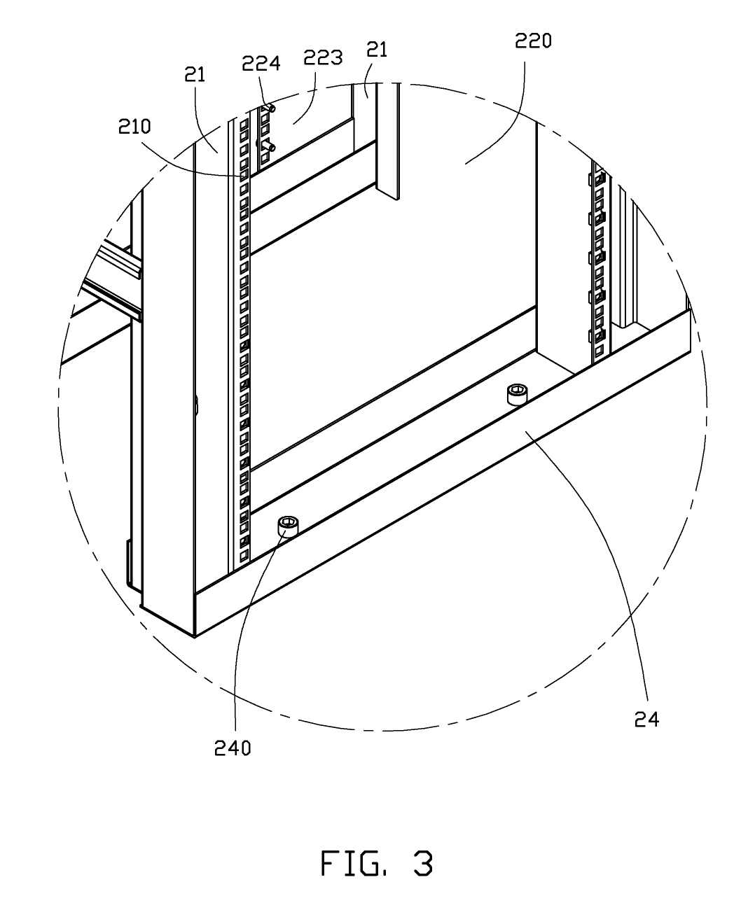

FIG. 4 is an enlarged, isometric view of a server and a fixing piece used in the container data center of FIG. 1.

### DETAILED DESCRIPTION

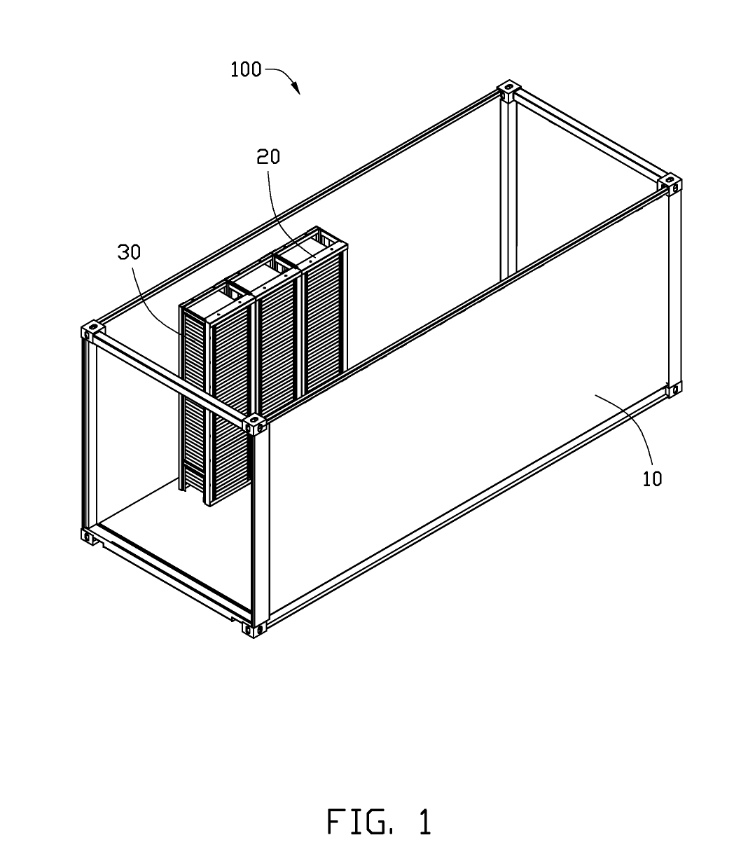

Referring to FIG. 1, a container data center 100 according to an embodiment is shown. The container data center 100 includes a container 10, a multiplicity of racks 20 (only three shown) received in the container 10, and a multiplicity of servers 30 mounted on the racks 20.

For showing the internal structure of the container data center 100 clearly, a top wall and two end walls of the container 10 are not shown.

The racks 20 are mounted in the container 10. Each of the racks 20 includes four elongated beams 21 respectively positioned at four corners of the rack 20, the beams 21 cooperatively defining an accommodating space 22 therebetween. The accommodating space 22 includes two opposite front and rear openings 220, 221. The front opening 220 is located between two of the beams 21 at the front of the rack 20. The rear opening 221 is located between the other two beams 21 at the rear of the rack 20. The front opening 220 provides access to install the servers 30. Each rack 20 further includes a plurality of first connecting pieces 23 positioned at the tops of the openings 220, 221, a plurality of second connecting pieces 24 positioned at the bottoms of the openings 220, 221, and a plurality of third connecting pieces 25 perpendicular to the first connecting pieces 23 and the second connecting pieces 24. The first, second, and third connecting pieces 23, 24, 25 connect the beams 21 together. The second connecting pieces 24 define a plurality of fixing holes (not shown). Each of the beams 21 defines a plurality of spaced loading holes 210 adjacent to the respective openings 220, 221. In the present embodiment, a right rear one of the beams 21 includes a main body (not labeled), and a plate 223 extending from the main body. The loading holes 210 of the right rear beam 21 are defined in the plate 223.

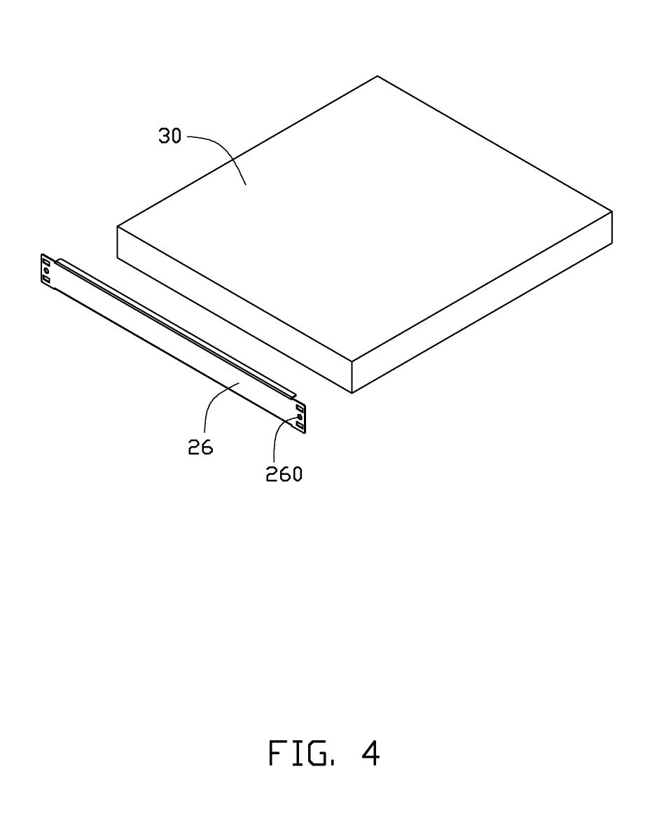

Referring also to FIG. 4, each of the racks 20 further includes a plurality of fixing pieces 26. Each of the fixing pieces 26 defines two holes 260 at two ends thereof, respectively, corresponding to any selected two of the loading holes 210. The top side and the bottom side of the fixing pieces 26 are bent perpendicularly to form two opposite flanges to hold a front or a back of a corresponding server 30 therebetween.

In assembly, a plurality of the fixing pieces 26 are installed in the rear opening 221. The fixing pieces 26 are fixed on the two rear beams 21 by pins 224 extending through the holes 260 and the loading holes 210. Then the rack 20 is fixed in the container 10 by a plurality of fasteners 240 (such as bolts or screws) extending through the fixing holes of the second connecting pieces 24 and through holes (not visible) defined in a bottom wall of the container 10. In this position, the rear opening 221 is located adjacent to a corresponding one of two opposite sidewalls of the container 10. Finally, each server 30 is inserted into the accommodating space 22 through the front opening 220. A rear end of the server 30 is held by one of the fixing pieces 26 at the rear opening 221. Another fixing piece 26 is installed in the front opening 220, and fixed on the two front beams 21 by pins 224 extending through the holes 260 and through two corresponding loading holes 210. Thus, a front end of the server 30 is held by the other fixing piece 26. In this way, the server 30 is firmly and securely mounted in the rack 20.

It will be understood that the above particular embodiments are shown and described by way of illustration only. The principles and the features of the present disclosure may be employed in various and numerous embodiments thereof without departing from the scope of the disclosure. The above-described embodiments illustrate the scope of the disclosure but do not restrict the scope of the disclosure.

What is claimed is:

1. A container data center comprising:
a container comprising a bottom wall; and
at least one rack received in the container, each of the at least one rack comprising:
four elongated beams respectively positioned at four corners of the rack and cooperatively defining an accommodating space therebetween for receiving servers therein; and
a plurality of connecting pieces connecting the beams together, wherein at least two of the connecting pieces are adjacent to the bottom wall of the container and are fixed on the bottom wall by fasteners.

2. The container data center of claim 1, wherein the accommodating space comprises two opposite openings, and the servers are able to pass through at least one of the openings when the servers are installed in the at least one rack.

3. The container data center of claim 2, wherein each of the racks further comprises a plurality of pairs of fixing pieces, each of the beams defines a plurality of spaced loading holes adjacent to the openings, and each pair of fixing pieces are positioned opposite each other in the two opposite openings and fixed on the beams by pins extended through corresponding one of the loading holes such that the pair of fixing pieces are able to hold one of the servers.

4. The container data center of claim 3, wherein each of the fixing pieces comprises opposite top and bottom flanges bent from a main body thereof, the flanges configured to hold an end of a corresponding one of the servers.

5. The container data center of claim 1, wherein the fasteners are selected from the group consisting of bolts and screws.

6. The container data center of claim 2, wherein the plurality of connecting pieces comprise a plurality of first connecting pieces positioned at the tops of the openings, a plurality of second connecting pieces positioned at the bottoms of the openings, and a plurality of third connecting pieces perpendicular to the first connecting pieces and the second connecting pieces.

7. The container data center of claim 3, wherein at least one of the beams comprises a main body and a plate extending from the main body, and the loading holes of the at least one of the beams are defined in the plate.

8. A container data center comprising:
a container comprising a bottom wall;
a plurality of racks received in the container, each of the racks comprising:
a plurality of elongated beams respectively positioned at corners of the rack and cooperatively defining an accommodating space therebetween; and
a plurality of connecting pieces connecting the beams together, wherein at least two of the connecting pieces are adjacent to the bottom wall of the container and are fixed on the bottom wall by fasteners; and
at least one server received in the accommodating space of at least one of the racks.

9. The container data center of claim 8, wherein the accommodating space comprises two opposite openings, and the servers are able to pass through at least one of the openings when the servers are installed in the at least one rack.

10. The container data center of claim 9, wherein each of the racks further comprises a plurality of pairs of fixing pieces, each of the beams defines a plurality of spaced loading holes adjacent to the openings, and each pair of the fixing pieces are positioned opposite each other in the two opposite openings and fixed on the beams by pins extended through the loading holes such that the pair of the fixing pieces are able to hold one of the servers.

11. The container data center of claim 10, wherein each of the fixing pieces comprises opposite top and bottom flanges bent from a main body thereof, the flanges configured to hold an end of the one of the servers.

12. The container data center of claim 8, wherein the fasteners are selected from the group consisting of bolts and screws.

13. The container data center of claim 9, wherein the plurality of connecting pieces comprise a plurality of first connecting pieces positioned at the tops of the openings, a plurality of second connecting pieces positioned at the bottoms of the openings, and a plurality of third connecting pieces perpendicular to the first connecting pieces and the second connecting pieces.

14. The container data center of claim 10, wherein at least one of the beams comprises a main body and a plate extending from the main body, and the loading holes of the at least one of the beams are defined in the plate.
